(19) United States
(12) Patent Application Publication
(10) Pub. No.: US 2017/0345453 A1
(43) Pub. Date: Nov. 30, 2017

(54) MAGNETIC RECORDING MEDIUM, METHOD FOR MANUFACTURING THE SAME, AND FILM FORMING DEVICE

(71) Applicant: Sony Corporation, Tokyo (KR)

(72) Inventors: Takashi AIZAWA, Miyagi (JP); Atsuhiro ABE, Kanagawa (JP)

(21) Appl. No.: 15/536,546

(22) PCT Filed: Nov. 12, 2015
(86) PCT No.: PCT/JP2015/005665

§ 371 Date: Jun. 15, 2017

(30) Foreign Application Priority Data
Dec. 29, 2014 (JP) 2014-267069

(51) Int. Cl. G11B 5/851; C23C 14/14; C23C 14/00; C23C 14/08; G11B 5/65; C23C 14/54

(52) U.S. Cl. CPC G11B 5/851; G11B 5/656; C23C 14/54; C23C 14/0036; C23C 14/08; C23C 14/14

(57) ABSTRACT

A film forming device includes a drum having a circumferential surface, a cathode accommodation unit disposed to be opposite to the circumferential surface, a first gas introducing unit which introduces a first gas into the cathode accommodation unit, and a second gas introducing unit which introduces a second gas between the circumferential surface and the cathode accommodation unit.

### TECHNICAL FIELD

The present technology relates to a magnetic recording medium including a flexible substrate and a magnetic layer, a method for manufacturing the same, and a film forming device for producing the magnetic recording medium.

### BACKGROUND ART

In recent years, in accordance with the development of information technology (IT) society, digitization of libraries, archives, and the like, and long-term storage of business documents, there have been increasing demands for higher recording density on magnetic tape for data storage.

As a method for manufacturing magnetic tape with high recording density, a method has been proposed in which while an elongated flexible substrate is allowed to travel, a laminated film is formed on the substrate by a sputtering method, a vapor deposition method, or the like (for example, see Patent Documents 1 to 3).

### CITATION LIST

### Patent Document

Patent Document 1: Japanese Patent Application Laid-Open No. 2006-286115
Patent Document 2: Japanese Patent Application Laid-Open No. 2005-353191
Patent Document 3: Japanese Patent Application Laid-Open No. 07-110939

### SUMMARY OF THE INVENTION

### Problems to be Solved by the Invention

An object of the present technology is to provide a magnetic recording medium with excellent reliability, a method for manufacturing the same, and a film forming device for producing the same.

### Solutions to Problems

For the purpose of solving the above problem, first technology is a film forming device including a drum having a circumferential surface, a cathode accommodation unit disposed to be opposite to the circumferential surface, a first gas introducing unit which introduces a first gas into the cathode accommodation unit, and a second gas introducing unit which introduces a second gas between the circumferential surface and the cathode accommodation unit.

Second technology is a film forming device including a drum having a circumferential surface, a plurality of cathode accommodation units disposed to be opposite to the circumferential surface, a first gas introducing unit which introduces a first gas into the plurality of cathode accommodation units, and a second gas introducing unit which introduces a second gas between the circumferential surface and at least one cathode accommodation unit of the plurality of cathode accommodation units.

Third technology is a method for manufacturing a magnetic recording medium, the method including: forming a magnetic layer on a substrate which travels along a circumferential surface of a drum by sputtering a target accommodated in a cathode accommodation unit while introducing an inert gas into the cathode accommodation unit opposite to the circumferential surface of the drum and introducing an oxidation-reactive gas between the circumferential surface and the cathode accommodation unit.

Fourth technology is a magnetic recording medium including an elongated flexible substrate and a magnetic layer obtained by performing sputtering and including Co and Co oxide, in which variations in magnetic characteristics are within ±10% over a section extending 100 m in a machine direction of the substrate.

### Effects of the Invention

As described above, the present technology makes it possible to obtain a magnetic recording medium with excellent reliability.

### BRIEF DESCRIPTION OF DRAWINGS

FIG. 1 is a cross-sectional view illustrating an example of a configuration of a magnetic recording medium according to a first embodiment of the present technology.

FIG. 2 is a schematic diagram illustrating an example of a configuration of a film forming device according to the first embodiment of the present technology.

FIG. 3 is an enlarged cross-sectional view illustrating an example of a configuration of a cathode accommodation unit illustrated in FIG. 2.

FIG. 4 is a schematic diagram illustrating an example of a configuration of a film forming device according to a modification of the first embodiment of the present technology.

FIG. 5 is a cross-sectional view illustrating an example of a configuration of a magnetic recording medium according to a second embodiment of the present technology.

FIG. 6 is a schematic diagram illustrating an example of a configuration of a film forming device according to the second embodiment of the present technology.

FIG. 7A is a graph illustrating an O₂ gas introduction dependency of perpendicular coercivity Hc. FIG. 7B is a graph illustrating an O₂ gas introduction dependency of perpendicular squareness ratio Rs.

FIG. 8A is a graph illustrating changes in perpendicular coercivity Hc with respect to the lengths of sputter-deposited films. FIG. 8B is a graph illustrating changes in perpendicular squareness ratio Rs with respect to the lengths of the sputter-deposited films.

FIG. 9A is a graph illustrating a depth profile of a Co—CoO layer of Example 1-1. FIG. 9B is a graph illustrating a depth profile of a Co—CoO layer of Comparative Example 1-2.

FIG. 10A is a graph illustrating changes in perpendicular coercivity Hc with respect to the length of a sputter-deposited film. FIG. 10B is a graph illustrating changes in perpendicular squareness ratio Rs with respect to the length of the sputter-deposited film.

FIG. 11 is a graph illustrating changes in Ar gas pressure to a gap between a drum and a cathode accommodation unit.

### MODE FOR CARRYING OUT THE INVENTION

A second gas introducing unit preferably introduces a second gas between a circumferential surface of a drum and a cathode accommodation unit from an upstream or downstream side of the rotation of the drum (in other words, an upstream or downstream side of a traveling substrate), or from a side in a width direction of the circumferential surface of the drum.

A film forming device may include two or more second gas introducing units. For example, two second gas introducing units may be included to introduce the second gas from both of the upstream or downstream side of the rotation of the drum. Alternatively, the second gas may be introduced from both sides in the width direction of the circumferential surface of the drum.

Embodiments of the present technology will be described in the following order.

### 1 First Embodiment

1.1 Configuration of Magnetic Recording Medium

1.2 Configuration of Film Forming Device

1.3 Method for Manufacturing Magnetic Recording Medium

1.4 Modification

### 2 Second Embodiment

2.1 Configuration of Magnetic Recording Medium

2.2 Configuration of Film Forming Device

2.3 Method for Manufacturing Magnetic Recording Medium

2.4 Modification

### 1 First Embodiment

### [1.1 Configuration of Magnetic Recording Medium]

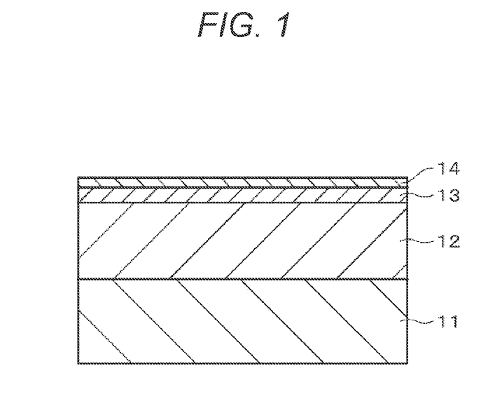

As illustrated in FIG. 1, a magnetic recording medium according to a first embodiment of the present technology includes an elongated substrate 11 and a magnetic recording layer 12 disposed on a surface of the substrate 11. The magnetic recording medium may further include, if necessary, a protective layer 13 disposed on a surface of the magnetic recording layer 12 and a lubricant layer 14 disposed on a surface of the protective layer 13. The magnetic recording medium is a so-called perpendicular magnetic recording medium.

Variations in magnetic characteristics of the magnetic recording medium, specifically, in magnetic characteristics of the magnetic recording layer are within ±10% over a section extending 100 m in a machine direction of the substrate 11. Here, the magnetic characteristics means at least one characteristic of, preferably both characteristics of perpendicular coercivity Hc and perpendicular squareness ratio Rs.

### (Substrate)

The substrate 11 to be used as a support is an elongated flexible non-magnetic substrate and includes a surface having a machine direction (MD) and a transverse direction (TD). An elongated film is preferably used as the above non-magnetic substrate. As a material of the non-magnetic substrate, for example, a flexible polymer resin material used for ordinary magnetic recording media can be used. Specific examples of the above polymer material include polyesters, polyolefins, cellulose derivatives, vinyl resins, polyimides, polyamides, polycarbonate and the like.

### (Magnetic Recording Layer)

The magnetic recording layer 12 which is a magnetic layer is a layer obtained by performing sputtering, in other words, a sputtered layer. It is possible to confirm whether the magnetic recording layer 12 is a sputtered layer, for example, by making an analysis to determine whether the magnetic recording layer 12 contains an inert gas. The magnetic recording layer 12 is a so-called perpendicularly magnetized film and includes Co and Co oxide, which are ferromagnets obtained by an oxidation reaction. The Co and Co oxide are included in the magnetic recording layer 12 in a mixed state. From the viewpoint of improving magnetic characteristics, the magnetic recording layer 12 preferably further includes Pt. Specifically, it is preferable to include, for example, CoPt—O or CoPtCr—O. If the magnetic recording layer 12 further includes Pt, the magnetic characteristics (for example, perpendicular coercivity Hc and perpendicular squareness ratio Rs) can be remarkably improved. Accordingly, it is possible to improve output of a recording/reproducing signal and to reduce noise as a magnetic recording medium. However, a Pt-free magnetic recording layer 12 is advantageous from the viewpoint of cost.

### (Protective Layer)

The protective layer 13 is provided for securing favorable traveling durability and corrosion resistance. The protective layer 13 includes, for example, a carbon material or silicon dioxide (SiO₂), and preferably includes the carbon material from the viewpoint of film strength of the protective layer 13. Examples of the carbon material include graphite, diamond-like carbon (DLC), diamond and the like.

### (Lubricant Layer)

The lubricant layer 14 is provided for improving traveling properties. The lubricant layer 14 includes a lubricant. As the lubricant, for example, a silicone lubricant, a hydrocarbon lubricant, a fluorinated hydrocarbon lubricant or the like can be used.

### (Effects)

In the magnetic recording medium with the above configuration, variations in magnetic characteristics are within ±10% over a section extending 100 m in a machine direction of the elongated substrate 11. Consequently, the magnetic characteristics of the magnetic recording medium can be stabilized in the machine direction thereof. In other words, it is possible to provide a magnetic recording medium with excellent reliability.

### [1.2 Configuration of Film Forming Device]

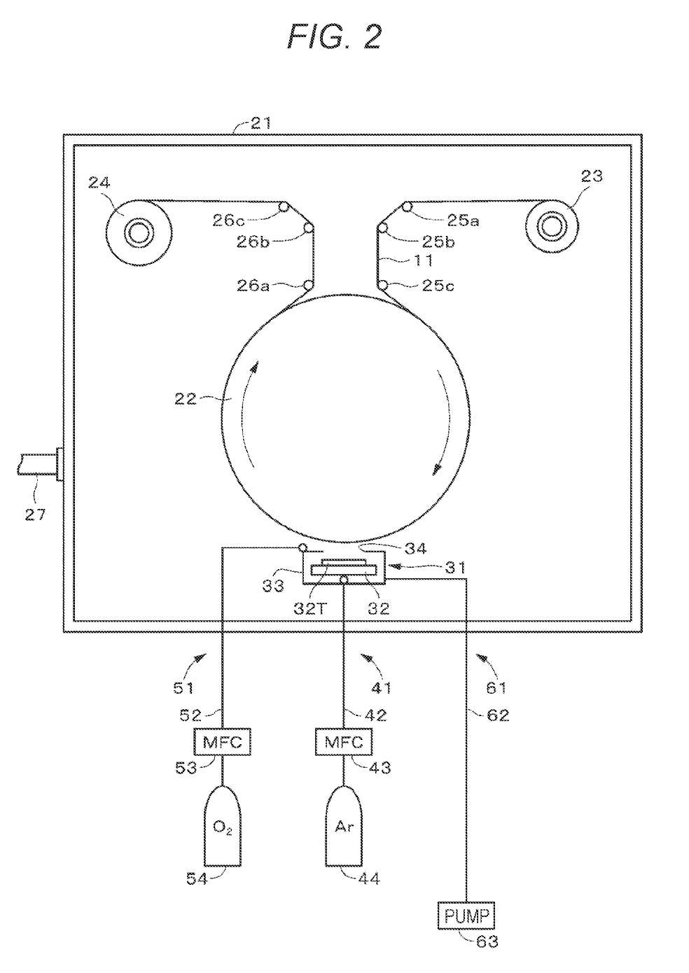

As illustrated in FIG. 2, the film forming device according to the first embodiment of the present technology is a sputtering device of a continuous take-up type, and includes a film forming chamber 21, a drum 22 which is a metal can (rotating body), a supply reel 23, a take-up reel 24, pluralities of guide rolls 25a to 25c and 26a to 26c, a cathode accommodation unit 31, gas introducing units 41 and 51, and an exhaust unit 61. The film forming device is, for example, a device employing a direct current (DC) magnetron sputtering method. However, a sputtering method is not limited to the method.

The film forming chamber 21 includes an exhaust pipe 27 and a vacuum pump (not illustrated) as an exhaust unit, and the exhaust unit sets an atmosphere in the film forming chamber 21 to have a predetermined degree of vacuum. The drum 22 having a rotatable configuration, the supply reel 23, and the take-up reel 24 are arranged in the film forming chamber 21. The plurality of guide rolls 25a to 25c for guiding transportation of the substrate 11 between the supply reel 23 and the drum 22, and the plurality of guide rolls 26a to 26c for guiding transportation of the substrate 11 between the drum 22 and the take-up reel 24 are disposed in the film forming chamber 21. When performing sputtering, the substrate 11 drawn from the supply reel 23 is taken up by the take-up reel 24 via the guide rolls 25a to 25c, the drum 22, and the guide rolls 26a to 26c. The drum 22 has a columnar or cylindrical shape, and the elongated substrate 11 is transported along a columnar or cylindrical circumferential surface of the drum 22. The drum 22 includes a cooling mechanism (not illustrated), and is cooled, for example, to about −20° C. when performing sputtering.

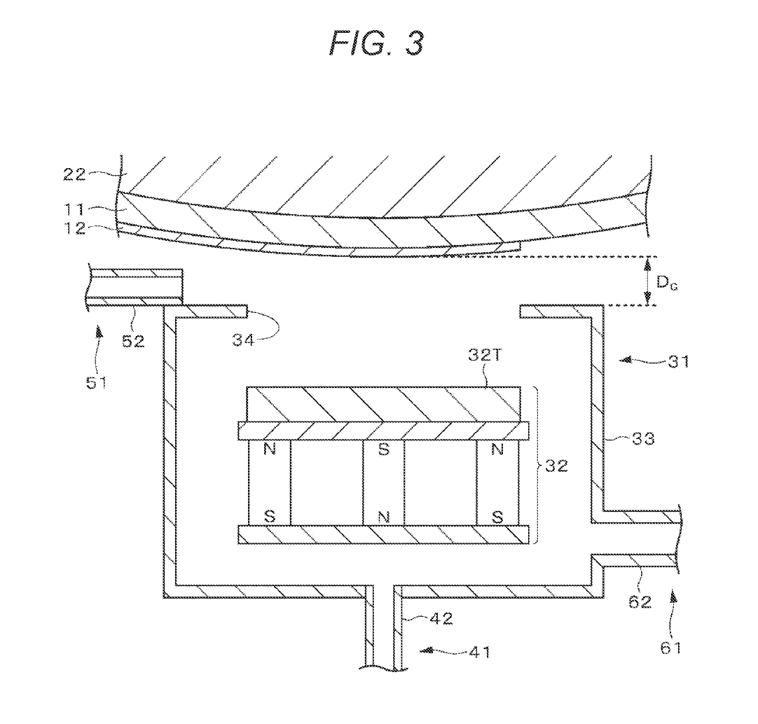

The cathode accommodation unit 31 is arranged to be opposite to the circumferential surface of the drum 22 in the film forming chamber 21. As illustrated in FIG. 3, the cathode accommodation unit 31 includes a cathode 32 and an accommodation chamber 33. The accommodation chamber 33 accommodates the cathode 32. A target 32T can be attached to the cathode 32. In a case where a magnetic recording layer 12 including Co and Co oxide is formed, a target including Co is used as the target 32T. In a case where a magnetic recording layer 12 further including Pt is formed, an alloy target including Co and Pt is used as the target 32T. Examples of the above alloy target include a CoPt alloy target and a CoPtCr alloy target.

The accommodation chamber 33 includes a wall portion having a configuration capable of performing heating and cooling. The wall portion has an opening 34 on a side opposite to the circumferential surface of the drum 22. During film production, sputtered particles sputtered from the target 32T and released into a gas phase reach, via the opening 34, the substrate 11 traveling along the circumferential surface of the drum 22, so that a thin film is formed.

The exhaust unit 61 is connected to the wall portion of the accommodation chamber 33. The exhaust unit 61 is provided for evacuating the interior of the accommodation chamber 33 independently from the film forming chamber 21. The exhaust unit 61 includes an exhaust pipe 62 and a vacuum pump 63. The accommodation chamber 33 and the vacuum pump 63 are connected by the exhaust pipe 62.

The gas introducing unit (first gas introducing unit) 41 is connected to the wall portion of the accommodation chamber 33. The gas introducing unit 41 is an inert gas introducing unit for introducing, into the accommodation chamber 33, an inert gas (first gas) for promoting plasma discharge.

The gas introducing unit 41 includes a gas introducing pipe 42, a mass flow controller (MFC) 43, and a gas cylinder 44 as a gas supply unit. One end of the gas introducing pipe 42 is connected to the accommodation chamber 33 via the wall portion of the film forming chamber 21. On the other hand, another end of the gas introducing pipe 42 is connected to the gas cylinder 44. The gas introducing pipe 42 is provided with the mass flow controller 43. The mass flow controller 43 controls a flow rate of the inert gas introduced into the accommodation chamber 33 from the gas cylinder 44. The mass flow controller 43 is preferably one used for an inert gas. The gas cylinder 44 encloses an inert gas. As the inert gas, for example, Ar gas or the like is used.

Into the film forming chamber 21, introduction is performed by the gas introducing unit (second gas introducing unit) 51. The gas introducing unit 51 is an oxidation-reactive gas introducing unit for introducing, between the circumferential surface of the drum 22 and the cathode accommodation unit 31, an oxidation-reactive gas (second gas). The gas introducing unit 51 introduces the oxidation-reactive gas between the circumferential surface of the drum 22 and the cathode accommodation unit 31 from a downstream side of the rotation of the drum 22, in other words, a downstream side of the traveling substrate 11.

The gas introducing unit 51 includes a gas introducing pipe 52, a mass flow controller 53, and a gas cylinder 54 as a gas supply unit. One end of the gas introducing pipe 52 is introduced into a position located at the downstream side of the rotation of the drum 22 in a perimeter of the opening 34 of the accommodation chamber 33, via the wall portion of the film forming chamber 21. On the other hand, another end of the gas introducing pipe 52 is connected to the gas cylinder 54. At the one end of the gas introducing pipe 52 introduced into the perimeter of the opening 34 of the accommodation chamber 33, a number of holes for blowing the oxidation-reactive gas are disposed. The gas introducing pipe 52 is provided with the mass flow controller 53. The mass flow controller 53 controls a flow rate of the oxidation-reactive gas introduced into the accommodation chamber 33 from the gas cylinder 54. The mass flow controller 53 is preferably one used for an oxidation-reactive gas. The gas cylinder 54 encloses an oxidation-reactive gas. As the oxidation-reactive gas, for example, oxygen or a compound including oxygen is used.

A gap is provided between the circumferential surface of the drum 22 and the cathode accommodation unit 31. A width D_{G} of the gap is preferably from 0.5 mm to 5.0 mm. If the width D_{G} is 0.5 mm, there may be a risk that the traveling substrate 11 contacts the cathode accommodation unit 31. On the other hand, if the width D_{G} exceeds 5.0 mm, there may be a risk that the Ar gas diffuses outside from the cathode accommodation unit 31 to make the discharge unstable.

### (Effects)

The film forming device having the above configuration includes the drum 22 having a circumferential surface, the cathode accommodation unit 31 disposed to be opposite to the circumferential surface of the drum 22, the gas introducing unit 41 which introduces an inert gas into the cathode accommodation unit 31, and the gas introducing unit 51 which introduces an oxidation-reactive gas between the circumferential surface of the drum 22 and the cathode accommodation unit 31. During film production, the gas introducing unit 41 introduces an inert gas for promoting plasma discharge into the accommodation chamber 33 in the cathode accommodation unit 31. In addition, the gas introducing unit 51 introduces an oxidation-reactive gas between the circumferential surface of the drum 22 and the opening 34 of the cathode accommodation unit 31. Consequently, it is possible, between the circumferential surface of the drum 22 and a sputtering surface of the target 32T, to make a concentration of the oxidation-reactive gas lower on a side of the sputtering surface of the target 32T than on a side of the circumferential surface of the drum 22, and to make a concentration of the inert gas higher on the side of the sputtering surface of the target 32T than on the side of the circumferential surface of the drum 22. For this reason, it is possible to suppress oxidation of the sputtering surface of the target 32T caused by the oxidation-reactive gas. Accordingly, characteristics of a thin film to be successively formed on the traveling substrate 11 can be maintained stably for a long period of time.

The film forming device having the above configuration can successively form the magnetic recording layer 12 on the substrate 11 traveling along the circumferential surface of the drum 22 while drawing the elongated substrate 11 from the supply reel 23 and taking up the elongated substrate 11 by the take-up reel 24. Accordingly, the magnetic recording layer 12 can be successively formed by a roll-to-roll method.

### [1.3 Method for Manufacturing Magnetic Recording Medium]

Hereinbelow, an example of a method for manufacturing the magnetic recording medium according to the first embodiment of the present technology will be described with reference to FIG. 2.

### (Evacuation Step)

First, the film forming chamber 21 and the accommodation chamber 33 are evacuated to achieve a predetermined degree of vacuum. More specifically, the film forming chamber 21 is evacuated to achieve the predetermined degree of vacuum in the film forming chamber 21. Thereafter, the accommodation chamber 33 is evacuated to achieve the predetermined degree of vacuum in the accommodation chamber 33. Alternatively, the film forming chamber 21 and the accommodation chamber 33 are evacuated simultaneously to achieve the predetermined degree of vacuum in the accommodation chamber 33. The degree of vacuum achieved in the accommodation chamber 33 is preferably 5.0×10⁻⁵ Pa or lower. That is because the magnetic recording layer 12 with favorable characteristics can be formed. In a state where the accommodation chamber 33 has been evacuated as described above, generally there remain gasses such as O₂ or H₂O on an inner wall surface of the accommodation chamber 33.

### (Heat Treatment Step)

It is preferable to perform a heat treatment of the wall portion of the accommodation chamber 33 next. That is because remaining gasses such as O₂ or H₂O can be released from the inner wall surface of the accommodation chamber 33, consequently. From the viewpoint of reducing the remaining gasses, it is preferable to perform the heat treatment such that the inner wall surface of the accommodation chamber 33 is maintained at 200° C. or higher for 30 minutes or longer.

### (Magnetic Recording Layer Forming Step)

Next, the magnetic recording layer 12 is successively formed in the following manner on the elongated substrate 11 traveling along the circumferential surface of the drum 22 while drawing the elongated substrate 11 from the supply reel 23 and taking up the elongated substrate 11 by the take-up reel 24. In other words, the target 32T set in the cathode 32 is sputtered while introducing the inert gas such as Ar gas into the film forming chamber 21 by the gas introducing unit 41 and introducing the oxidation-reactive gas such as O₂ gas between the circumferential surface of the drum 22 and the opening 34 of the cathode accommodation unit 31 by the gas introducing unit 51. Consequently, the magnetic recording layer 12 is formed on the surface of the substrate 11 traveling along the circumferential surface of the drum 22.

In a case where the target 32T is a target including Co, a magnetic recording layer 12 including Co—CoO is formed. In a case where the target 32T is a target including a CoPt alloy, a magnetic recording layer 12 including CoPt—O is formed. In a case where the target 32T is a target including a CoPtCr alloy, a magnetic recording layer 12 including CoPtCr—O is formed.

It is preferable to perform a cool treatment of the wall portion of the accommodation chamber 33 during the film forming step described above. That is because release of the remaining gasses such as O₂ or H₂O left on the inner wall surface of the accommodation chamber 33 can be consequently suppressed. From the viewpoint of suppressing the release of the remaining gasses, it is preferable to maintain a temperature of the inner wall surface of the accommodation chamber 33 at 90° C. or lower during the film forming step.

### (Protective Layer Forming Step)

Next, for example, the substrate 11 taken up by the take-up reel 24 is transported from the film forming device to another film forming device to form the protective layer 13 on the surface of the magnetic recording layer 12. As a method for forming the protective layer 13, for example, a chemical vapor deposition (CVD) method or a physical vapor deposition (PVD) method can be used.

### (Lubricant Layer Forming Step)

Next, for example, the substrate 11 is transported to an application device, a lubricant and the like are applied onto the surface of the protective layer 13 to form the lubricant layer 14. As a method for applying the lubricant, for example, various application methods such as a gravure coating method and a dip coating method can be used. Through the above, the magnetic recording medium illustrated in FIG. 1 is obtained.

### (Effects)

In the method for manufacturing a magnetic recording medium including the above steps, the target 32T accommodated in the cathode accommodation unit 31 is sputtered while introducing the inert gas into the cathode accommodation unit 31 opposite to the circumferential surface of the drum 22 and introducing the oxidation-reactive gas between the circumferential surface of the drum 22 and the cathode accommodation unit 31. Consequently, the magnetic recording layer 12 is formed on the elongated substrate 11 traveling along the circumferential surface of the drum 22. Accordingly, it is possible, between the circumferential surface of the drum 22 and a sputtering surface of the target 32T, to make a concentration of the oxidation-reactive gas lower on a side of the sputtering surface of the target 32T than on a side of the circumferential surface of the drum 22, and to make a concentration of the inert gas higher on the side of the sputtering surface of the target 32T than on the side of the circumferential surface of the drum 22. For this reason, it is possible to suppress oxidation of the sputtering surface of the target 32T caused by the oxidation-reactive gas. In other words, variations in the magnetic characteristics of the magnetic recording medium can be suppressed over a long section in the machine direction of the elongated substrate 11. The variations in the magnetic characteristics of the magnetic recording medium can be suppressed to be within ±10%, for example, over a section extending 100 m.

### [1.4 Modification]

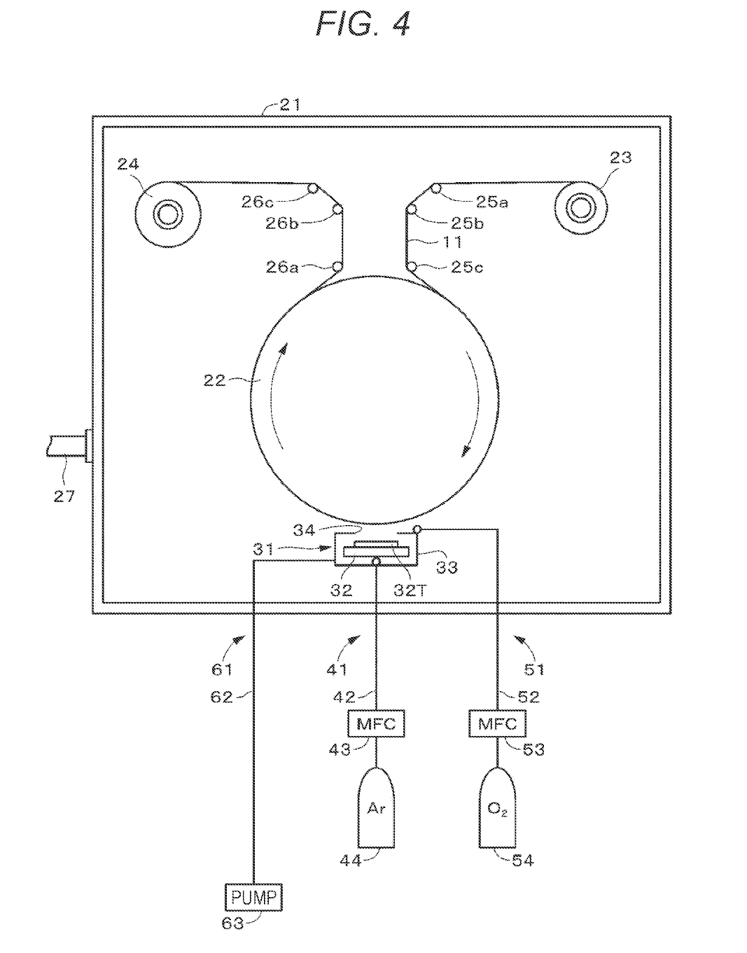

As illustrated in FIG. 4, the gas introducing unit 51 may introduce the oxidation-reactive gas between the circumferential surface of the drum 22 and the cathode accommodation unit 31 from an upstream side of the rotation of the drum 22, in other words, an upstream side of the traveling substrate 11. In that case, one end of the gas introducing pipe 52 is introduced into a position located at the upstream side of the rotation of the drum 22 in a perimeter of the opening 34 of the accommodation chamber 33, via the wall portion of the film forming chamber 21.

The film forming device may include two gas introducing units 51 and the oxidation-reactive gas may be introduced between the circumferential surface of the drum 22 and the cathode accommodation unit 31 from both of the upstream and downstream sides of the rotation of the drum 22.

The film forming device may include a gas introducing unit which introduces the oxidation-reactive gas between the circumferential surface of the drum 22 and the cathode accommodation unit 31 from four directions or all directions. In that case, the gas introducing pipe may have an annular gas blowing unit at one end thereof, and the annular gas blowing unit may be disposed to surround the opening 34 of the accommodation chamber 33.

The film forming device may include, instead of the gas introducing unit 51 which introduces the oxidation-reactive gas, a gas introducing unit which introduces a nitrogen-reactive gas such as a nitrogen gas. If such a gas introducing unit is included, it is possible to form a thin film containing nitrogen on an elongated substrate.

### 2 Second Embodiment

### [2.1 Configuration of Magnetic Recording Medium]

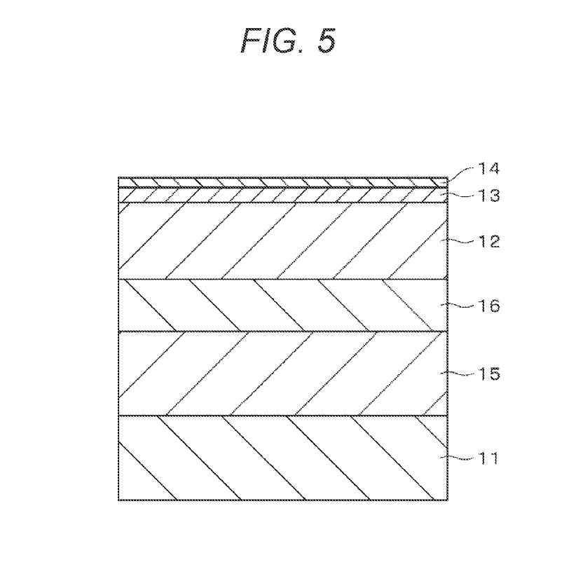

As illustrated in FIG. 5, a magnetic recording medium according to a second embodiment of the present technology differs from the magnetic recording medium according to the first embodiment in that an undercoat layer 15 and an intermediate layer (seed layer) 16 disposed between a substrate 11 and a magnetic recording layer 12 are further included. The undercoat layer 15 is disposed on the surface of the substrate 11, the intermediate layer 16 is disposed on a surface of the undercoat layer 15, and the magnetic recording layer 12 is disposed on a surface of the intermediate layer 16. In the magnetic recording medium according to the second embodiment, a portion similar to that of the magnetic recording medium according to the first embodiment will be denoted by the same reference sign, and a description thereof will be omitted.

### (Undercoat Layer)

The undercoat layer 15 includes an alloy including Ti and Cr, and preferably has an amorphous state. The alloy may further include oxygen (O). Here, the term “alloy” means at least one type of a solid solution, a eutectic, and an intermetallic compound, each of which including Ti and Cr. The term “amorphous state” means that a halo is observed in an electron diffraction method and a crystalline structure cannot be specified.

The undercoat layer 15 which includes the alloy including Ti and Cr, and has an amorphous state has functions to suppress influences of O₂ gas or H₂O adsorbed to the substrate 11 and to reduce unevenness of the surface of the substrate 11 to form a metallic smooth surface on the surface of the substrate 11. The functions improve vertical orientation of the intermediate layer 16. It should be noted that when the undercoat layer 15 is brought into a crystalline state, a columnar shape accompanying crystal growth is more clearly exhibited, unevenness of the surface of the substrate 11 is emphasized, and there may be a risk of deteriorated crystal orientation of the intermediate layer 16.

The alloy included in the undercoat layer 15 may further include, as an addition element, an element other than Ti and Cr. As the addition element, for example, one or more types of elements selected from the group including Nb, Ni, Mo, Al, W and the like are exemplified.

It should be noted that a structure of the undercoat layer 15 is not limited to a single-layer structure, and may be a multi-layer structure including two or more layers. For example, in a case where the undercoat layer 15 has a two-layer structure, the undercoat layer 15 includes a first undercoat layer (upper undercoat layer) and a second undercoat layer (lower undercoat layer). The first undercoat layer is disposed on a side of the intermediate layer 16, and the second undercoat layer is disposed on a side of the substrate 11. As the second undercoat layer, one similar to the above-described undercoat layer 15 can be used. The first undercoat layer includes, for example, a material of which a composition is different from that of the second undercoat layer. Specific examples of the material include NiW, Ta and the like. It should be noted that the first undercoat layer may be regarded as not an undercoat layer but an intermediate layer.

### (Intermediate Layer)

The intermediate layer 16 is provided for the purpose of micronization and improved orientation of crystal particles of the magnetic recording layer 12. The intermediate layer 16 includes one or more types of metal materials selected from the group including Co, Cu, Ni, Fe, Zr, Pt, Au, Ta, W, Ag, Al, Mn, Cr, Ti, V, Nb, Mo, Ru and the like. An alloy obtained by combining any two or more types thereof, a compound of the metal materials and oxygen or nitrogen, a compound such as silicon oxide, silicon nitride, indium tin oxide (ITO), In₂O₃, and ZrO, carbon, diamond-like carbon, or the like may be included. As the alloy, for example, a Ni alloy such as NiW is exemplified.

### (Effects)

Since the magnetic recording medium with the above configuration further includes the undercoat layer 15 and the intermediate layer 16 disposed between the substrate 11 and the magnetic recording layer 12, it is possible to further improve the magnetic characteristics than the magnetic recording medium according to the first embodiment.

### [2.2 Configuration of Film Forming Device]

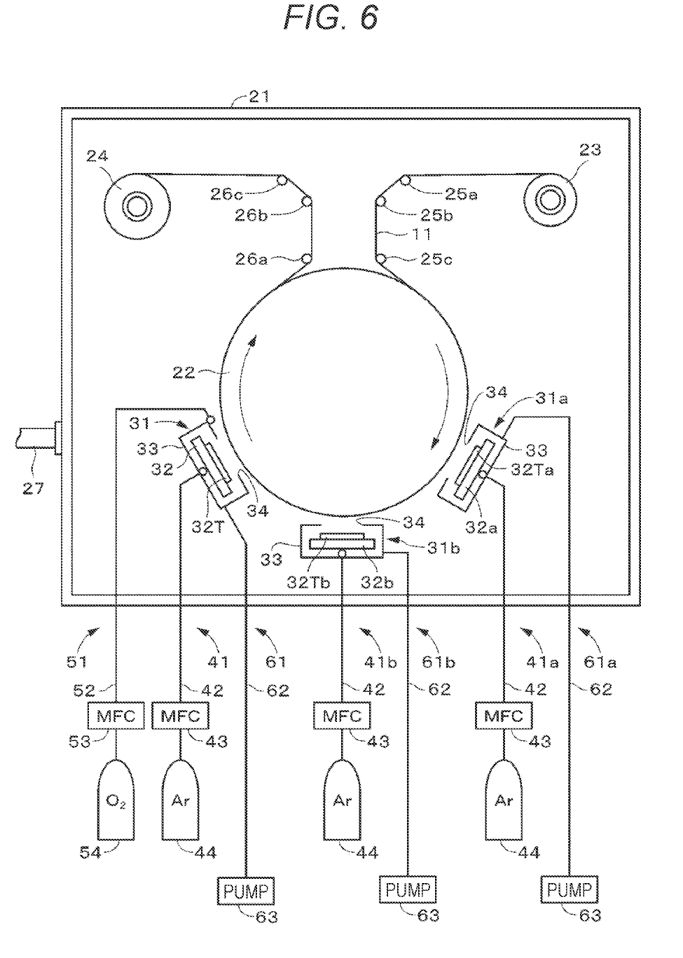

As illustrated in FIG. 6, a film forming device according to the second embodiment of the present technology differs from the film forming device according to the first embodiment in that cathode accommodation units 31a and 31b, gas introducing units 41a and 41b, and exhaust units 61a and 61b are further included. In the film forming device according to the second embodiment, a portion similar to that of the film forming device according to the first embodiment will be denoted by the same reference sign, and a description thereof will be omitted.

The cathode accommodation units 31a and 31b, and a cathode accommodation unit 31 are arranged to be opposite to a circumferential surface of a drum 22 in a film forming chamber 21. The cathode accommodation units 31a, 31b, and 31 are separately arranged in this order at predetermined intervals in a rotation direction of the drum 22.

The gas introducing unit (first gas introducing unit) 41a and the exhaust unit 61a are connected to an accommodation chamber 33 of the cathode accommodation unit 31a. A target 32Ta can be attached to a cathode 32a. As the target 32Ta, a target used for forming the undercoat layer 15 is set in a case of manufacturing the magnetic recording medium with the above configuration. A width D_{G} of a gap between the circumferential surface of the drum 22 and the cathode accommodation unit 31a is preferably from 0.5 mm to 5.0 mm.

The gas introducing unit (first gas introducing unit) 41b and the exhaust unit 61b are connected to an accommodation chamber 33 of the cathode accommodation unit 31b. A target 32Tb can be attached to a cathode 32b. As the target 32Tb, a target used for forming the intermediate layer 16 is set in a case of manufacturing the magnetic recording medium with the above configuration. A width D_{G} of a gap between the circumferential surface of the drum 22 and the cathode accommodation unit 31b is preferably from 0.5 mm to 5.0 mm.

### (Effects)

Since the film forming device having the above configuration further includes the cathode accommodation units 31a and 31b in addition to the cathode accommodation unit 31, it is possible to simultaneously form three layers of a laminated film configured by, for example, the undercoat layer 15, the intermediate layer 16, and the magnetic recording layer 12, by transporting the substrate 11 once.

The film forming device includes exhaust mechanisms which exhaust the cathode accommodation units independently. Specifically, the film forming device includes an exhaust unit 61, the exhaust units 61a and 61b which respectively exhaust the cathode accommodation units 31, 31a, and 31b independently. Consequently, it is possible to respectively adjust the degree of vacuum in the cathode accommodation units 31, 31a, and 31b in accordance with characteristics required for respective thin films to be formed by the cathode accommodation units 31, 31a, and 31b.

### [2.3 Method for Manufacturing Magnetic Recording Medium]

Hereinbelow, an example of a method for manufacturing the magnetic recording medium according to the second embodiment of the present technology will be described with reference to FIG. 6.

### (Evacuation Step)

First, the film forming chamber 21 and the respective accommodation chambers 33 of the cathode accommodation units 31, 31a, and 31b are evacuated to achieve a predetermined degree of vacuum. More specifically, the film forming chamber 21 is evacuated to achieve the predetermined degree of vacuum in the film forming chamber 21. Thereafter, the respective accommodation chambers 33 of the cathode accommodation units 31, 31a, and 31b are evacuated to achieve the predetermined degree of vacuum in the respective chambers. Alternatively, the film forming chamber 21 and the respective accommodation chambers 33 of the cathode accommodation units 31, 31a, and 31b are evacuated simultaneously to achieve the predetermined degree of vacuum in the respective chambers of the cathode accommodation units 31, 31a, and 31b. The degree of vacuum achieved in the respective accommodation chambers 33 of the cathode accommodation units 31, 31a, and 31b is preferably 5.0×10⁻⁵ Pa or lower. That is because the undercoat layer 15, the intermediate layer 16, and the magnetic recording layer 12 with favorable characteristics can be formed.

### (Heat Treatment Step)

It is preferable to perform a heat treatment of a wall portion of the respective accommodation chambers 33 of the cathode accommodation units 31, 31a, and 31b next.

### (Undercoat Layer, Intermediate Layer, and Magnetic Recording Layer Forming Steps)

Next, the undercoat layer 15, the intermediate layer 16, and the magnetic recording layer 12 are successively formed in the following manner on the elongated substrate 11 traveling along the circumferential surface of the drum 22 while drawing the elongated substrate 11 from a supply reel 23 and taking up the elongated substrate 11 by a take-up reel 24.

In the cathode accommodation unit 31a, the target 32Ta set in the cathode 32a is sputtered while introducing an inert gas such as Ar gas into the accommodation chamber 33 by the gas introducing unit 41a. Consequently, the undercoat layer 15 is formed on the substrate 11 traveling along the circumferential surface of the drum 22.

In the cathode accommodation unit 31b, the target 32Tb set in the cathode 32b is sputtered while introducing an inert gas such as Ar gas into the accommodation chamber 33 by the gas introducing unit 41b, and thereby the intermediate layer 16 is formed on the undercoat layer 15 on the substrate 11 traveling along the circumferential surface of the drum 22.

In the cathode accommodation unit 31, the magnetic recording layer 12 is formed on the intermediate layer 16 on the substrate 11 traveling along the circumferential surface of the drum 22 similarly to the first embodiment described above.

It is preferable to perform a cool treatment of the wall portion of the respective accommodation chambers 33 of the cathode accommodation units 31, 31a, and 31b during the film forming step described above.

### (Protective Layer and Lubricant Layer Forming Steps)

Protective layer and lubricant layer forming steps are similar to those in the method for manufacturing the magnetic recording medium according to the first embodiment.

### (Effects)

In the method for manufacturing a magnetic recording medium including the above steps, it is possible to produce a magnetic recording medium including the undercoat layer 15, the intermediate layer 16, and the magnetic recording layer 12, while suppressing variations in the magnetic characteristics over a long section in the machine direction of the elongated substrate 11.

### [2.4 Modification]

In the second embodiment described above, the example has been described in which the magnetic recording medium includes both of the undercoat layer 15 and the intermediate layer 16 between the substrate 11 and the magnetic recording layer 12. However, one of the undercoat layer 15 and the intermediate layer 16 may be included. In that case, it is sufficient that the film forming device includes one of the cathode accommodation unit 31a and the cathode accommodation unit 31b. In addition, regarding the method for manufacturing the magnetic recording medium, it is sufficient that the magnetic recording layer 12 is formed, after forming one of the undercoat layer 15 and the intermediate layer 16 on the surface of the substrate 11, on the surface of the formed layer.

In the second embodiment described above, the example has been described in which the film forming device includes three cathode accommodation units 31, 31a, and 31b. However, the film forming device may include two or four or more cathode accommodation units.

In the second embodiment described above, the example has been described in which the gas introducing unit is included which introduces a reactive gas between one accommodation unit of a plurality of cathode accommodation units and the circumferential surface of the drum 22. However, a gas introducing unit may be included which introduces a reactive gas between two or more accommodation units of the plurality of cathode accommodation units and the circumferential surface of the drum 22.

The configuration of the modification of the first embodiment described above may be adopted in the second embodiment.

### EXAMPLES

Hereinbelow, the present technology will be specifically described by Examples. However, the present technology is not limited exclusively to Examples below.

Examples of the present technology will be described in the following order.

i Relationship between O₂ gas Introduction Position and Magnetic Characteristics

### ii Magnetic Characteristics of CoPtCr—O Recording Layer

iii Relationship between Gap between Drum and Cathode Accommodation Unit and Gas Pressure

### i Relationship Between O₂ Gas Introduction Position and Magnetic Characteristics

### Examples 1-1 to 1-4

Magnetic tape was produced in the following manner using a film forming device having the configuration illustrated in FIGS. 2 and 3. First, a Co target was attached to a cathode. It should be noted that a width D_{G} of a gap between a circumferential surface of a drum and a cathode accommodation unit was set to 2.0 mm. Next, a film forming chamber and the cathode accommodation unit were independently evacuated. The degree of vacuum achieved in the cathode accommodation unit was adjusted to 5.0×10⁻⁵ Pa or lower.

Next, each wall portion of the cathode accommodation unit was heated and a temperature of an inner wall surface of the cathode accommodation unit was maintained at 200° C. or higher for 30 minutes or longer. Next, while drawing an elongated polymer film from a supply reel and taking up the elongated polymer film by a take-up reel, a Co—CoO layer was formed in the following manner on the polymer film traveling along the circumferential surface of the drum. In other words, the Co target attached to the cathode was sputtered while introducing Ar gas into the cathode accommodation unit by an Ar gas introducing unit and introducing O₂ gas between the circumferential surface of the drum and the cathode accommodation unit from a downstream side of the rotation of the drum by an O₂ gas introducing unit. Consequently, the Co—CoO layer was formed on the elongated polymer film traveling along the circumferential surface of the drum. It should be noted that an amount of the O₂ gas introduced was adjusted for each sample as indicated in Table 1. In addition, a temperature control was performed in which wall portions of the cathode accommodation unit were cooled and maintained at 90° C. or lower during film formation. Through the above, elongated magnetic tape was obtained.

### Reference Example 1-1

Elongated magnetic tape was obtained similarly to Example 1-1, except that the Co target was sputtered without introducing the O₂ gas by the O₂ gas introducing unit to form a Co layer on the elongated polymer film traveling along the circumferential surface of the drum.

### Examples 2-1 to 2-5

The film forming device having the configuration illustrated in FIG. 4 was used to introduce, via the O₂ gas introducing unit, the O₂ gas between the drum and the cathode accommodation unit from a downstream side of the rotation of the drum. In addition, an amount of the O₂ gas introduced was adjusted for each sample as indicated in Table 1. Elongated magnetic tape was obtained similarly to Examples 1-1 to 1-4 except for the points described above.

### Comparative Examples 1-1 to 1-3

As a film forming device, a device was prepared which is similar to that used in Reference Example 1-1 and Examples 1-1 to 1-4 except that both of the Ar gas introducing unit and the O₂ gas introducing unit were disposed at a position opposite to a rear surface of the cathode on the wall portion of the cathode accommodation unit. The film forming device was used to introduce the Ar gas and the O₂ gas into the cathode accommodation unit by the Ar gas introducing unit and the O₂ gas introducing unit, respectively. In addition, an amount of the O₂ gas introduced was adjusted for each sample as indicated in Table 1. Elongated magnetic tape was obtained similarly to Example 1-1 except for the points described above.

### Comparative Example 1-4

Elongated magnetic tape was obtained similarly to Comparative Example 1-1, except that the Co target was sputtered without introducing the O₂ gas by the O₂ gas introducing unit to forma Co layer on the elongated polymer film traveling along the circumferential surface of the drum.

### (Evaluation)

Each piece of the magnetic tape obtained as described above was evaluated in the following manner.

### (Magnetic Characteristics)

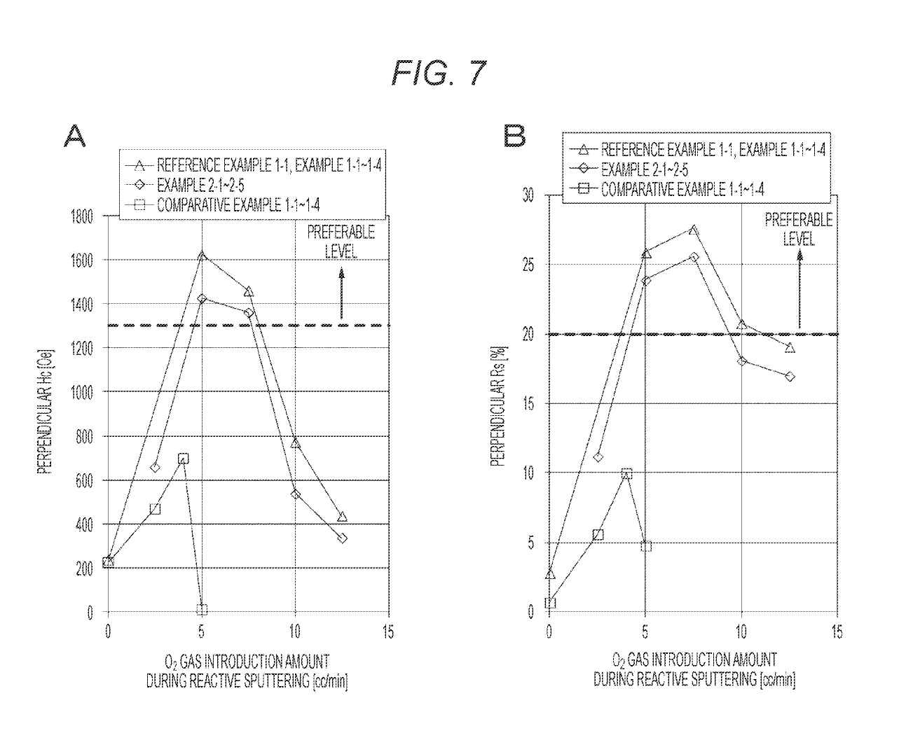

For the magnetic tape of each of Reference Example 1-1, Examples 1-1 to 1-4, Examples 2-1 to 2-5, and Comparative Examples 1-1 to 1-4, the perpendicular coercivity Hc and the perpendicular squareness ratio Rs at immediately after starting the film formation were measured by using a vibrating sample magnetometer (VSM). Results thereof are illustrated in Table 1 and FIGS. 7A and 7B.

Table 1 indicates amounts of the O₂ gas introduced and evaluation results of the magnetic characteristics for the magnetic tape of each of Reference Example 1-1, Examples 1-1 to 1-4, Examples 2-1 to 2-5, and Comparative Examples 1-1 to 1-4

TABLE 1

| | O₂ GAS | O₂ GAS | PERPEN- | PERPEN- |
|---|---|---|---|---|
| | INTRODUCTION | INTRODUCTION | DICULAR | DICULAR |
| | POSITION | AMOUNT (cc/min) | Hc (Oe) | Rs (%) |
| REFERENCE | — | 0.0 | 236 | 3 |
| EXAMPLE 1-1 | | | | |
| EXAMPLE 1-1 | BETWEEN DRUM | 5.0 | 1624 | 26 |
| EXAMPLE 1-2 | AND CATHODE | 7.5 | 1461 | 28 |
| EXAMPLE 1-3 | ACCOMMODATION | 10.0 | 772 | 21 |
| EXAMPLE 1-4 | UNIT | 12.5 | 436 | 19 |
| | (GAS IS | | | |
| | INTRODUCED FROM | | | |
| | DOWNSTREAM SIDE | | | |
| | OF TRAVELING) | | | |
| EXAMPLE 2-1 | BETWEEN DRUM | 2.5 | 658 | 11 |
| EXAMPLE 2-2 | AND CATHODE | 5.0 | 1427 | 24 |
| EXAMPLE 2-3 | ACCOMMODATION | 7.5 | 1361 | 26 |
| EXAMPLE 2-4 | UNIT | 10.0 | 536 | 18 |
| EXAMPLE 2-5 | (GAS IS | 12.5 | 336 | 17 |
| | INTRODUCED FROM | | | |
| | UPSTREAM SIDE OF | | | |
| | TRAVELING) | | | |
| COMPARATIVE | — | 0.0 | 225 | 1 |
| EXAMPLE 1-4 | | | | |
| COMPARATIVE | IN CATHODE | 2.5 | 469 | 6 |
| EXAMPLE 1-1 | ACCOMMODATION | | | |
| COMPARATIVE | UNIT | 4.0 | 699 | 10 |
| EXAMPLE 1-2 | | | | |
| COMPARATIVE | | 5.0 | 11 | 5 |
| EXAMPLE 1-3 | | | | |

In a case of employing the method for introducing O₂ gas between the drum and the cathode accommodation unit (hereinafter referred to as a “gas introduction method of Examples”), Hc and Rs remarkably increase in comparison to a case of employing the method for introducing O₂ gas into the cathode accommodation unit (hereinafter referred to as a “gas introduction method of Comparative Examples”). With the gas introduction method of Examples, Hc of 1300 Oe or more, and Rs of 20% or more can be obtained by adjusting an amount of O₂ gas introduced. However, with the gas introduction method of Comparative Examples, such Hc and Rs cannot be obtained even when adjusting an amount of O₂ gas introduced. The reason therefor is considered as follows. Formation of an oxide film on the surface of the Co target is suppressed in the gas introduction method of Examples in comparison to the gas introduction method of Comparative Examples.

### (Variations in Magnetic Characteristics)

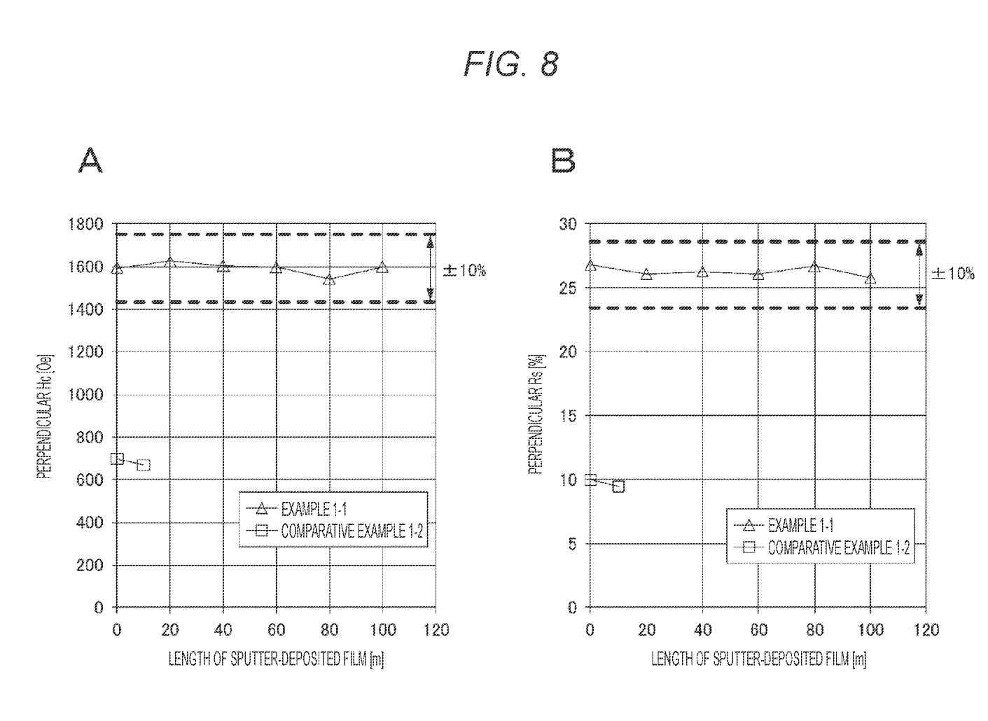

The perpendicular coercivity Hc and the perpendicular squareness ratio Rs of the magnetic tape of each of Example 1-1 and Comparative Example 1-2 were measured by using the VSM for every predetermined length of the formed film from immediately after starting the film formation. Results thereof are illustrated in FIGS. 8A and 8B. It should be noted that, regarding Comparative Example 1-2, the magnetic characteristics were poor at immediately after film formation, and therefore, magnetic characteristics at immediately after film formation, and at a length of the formed film of 10 m are only illustrated. However, there was a tendency for the magnetic characteristics to further deteriorate with an increase in the length of the formed film in Comparative Example 1-2.

In Example 1-2, Hc and Rs are high at immediately after film formation, and variations in Hc and Rs are within ±10% over a section extending 100 m in a machine direction of the magnetic tape. On the other hand, in Comparative Example 1-2, Hc and Rs are low at immediately after film formation, and variations in Hc and Rs are not within ±10% over a section extending 100 m in a machine direction of the magnetic tape.

### (Composition Analysis)

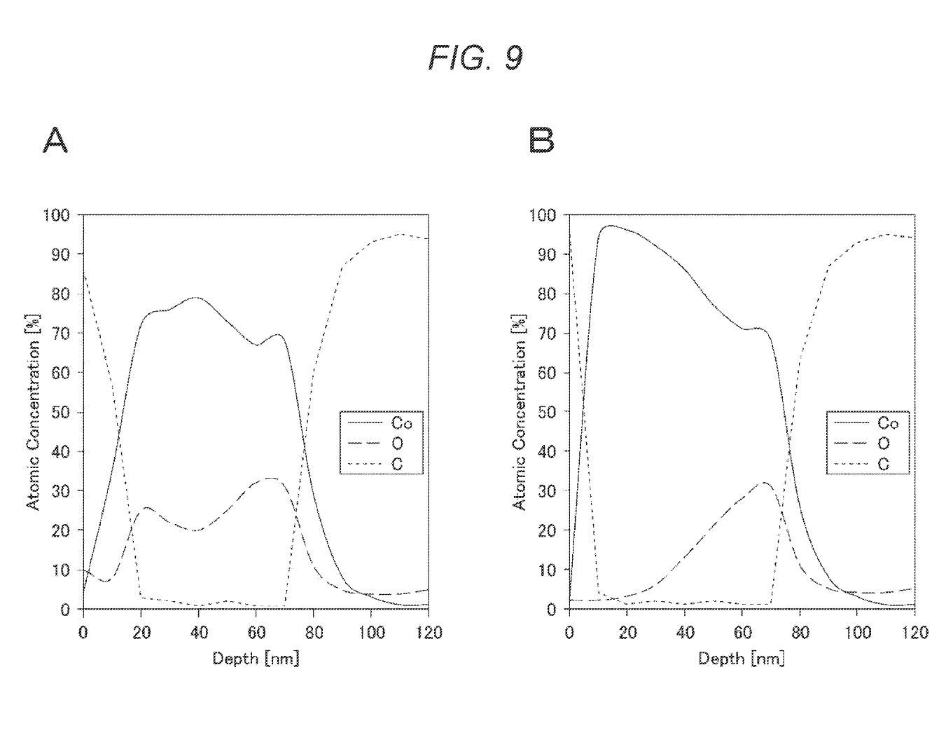

For the magnetic recording layer of the magnetic tape of each of Example 1-1 and Comparative Example 1-2, a composition analysis was performed in a depth direction using X-ray photoelectron spectroscopy (XPS). Results thereof are illustrated in FIGS. 9A and 9B.

It can be seen that an oxygen concentration is high around a depth of 20 to 40 nm in the Co—CoO layer of Example 1-1. The reason therefor is presumed as follows. Since the sputtering was performed while introducing O₂ gas between the circumferential surface of the drum and the cathode accommodation unit when the Co—CoO layer was sputter-deposited, oxygen was appropriately taken in the film. On the other hand, it can be seen that an oxygen concentration is low, and contrary, a Co concentration is high around a depth of 20 to 40 nm in the Co—CoO layer of Comparative Example 1-2. The reason therefor is presumed as follows. Since the sputtering was performed while introducing O₂ gas into the cathode accommodation unit when the Co—CoO layer was sputter-deposited, oxygen was not successfully taken in the film.

### ii Magnetic Characteristics of CoPtCr—O Recording Layer

### Example 3-1

Elongated magnetic tape was obtained similarly to Example 1-1 except that a CoPtCr alloy target was attached to the cathode and the Co—CoO layer was formed on the polymer film.

### (Variations in Magnetic Characteristics)

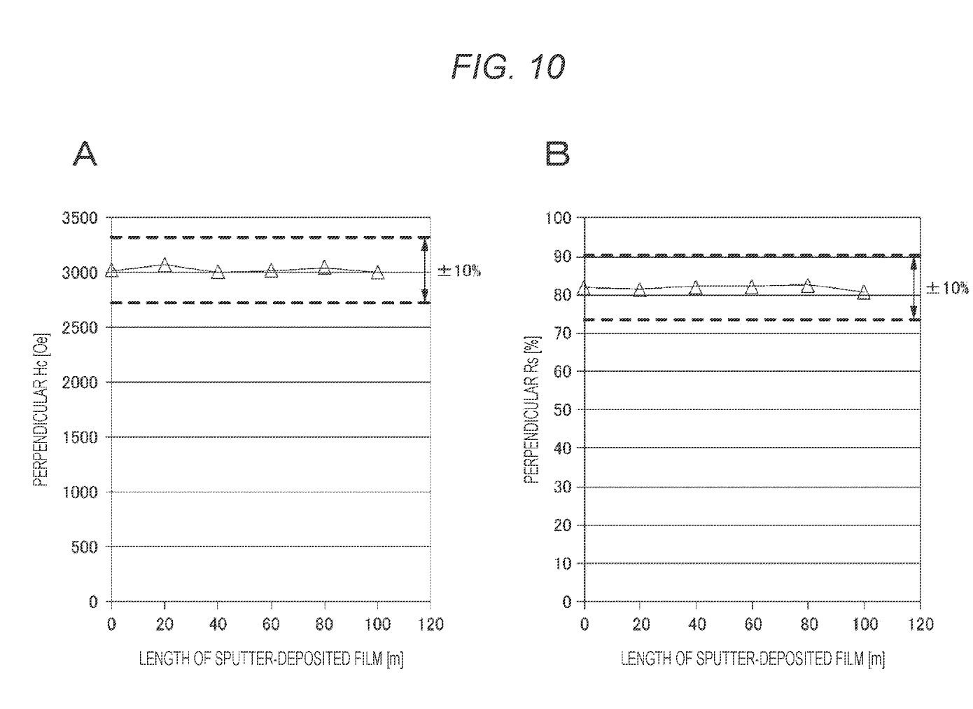

The perpendicular coercivity Hc and the perpendicular squareness ratio Rs of the magnetic tape of Example 3-1 were measured by using the VSM for every predetermined length of the formed film from immediately after starting the film formation. Results thereof are illustrated in FIGS. 10A and 10B.

Higher Hc and Rs were obtained in Example 3-1, in which the CoPtCr—O layer was formed using the CoPtCr target, in comparison to Example 1-1, in which the Co—CoO layer was formed using the Co target. In Example 3-1, Hc and Rs are as high as about 3000 Oe and about 80%, respectively, at immediately after film formation, and variations in Hc and Rs are within ±10% over a section extending 100 m in a machine direction of the magnetic tape.

### iii Relationship Between Gap Between Drum and Cathode Accommodation Unit and Gas Pressure

### Examples 4-1 to 4-11

A film forming device with the configuration illustrated in FIG. 2, in which a width D_{G} of a gap between a drum and a cathode accommodation unit had been adjusted to be in a range of 0.5 mm to 10 mm was prepared.

### (Ar Gas Pressure in Cathode Accommodation Unit)

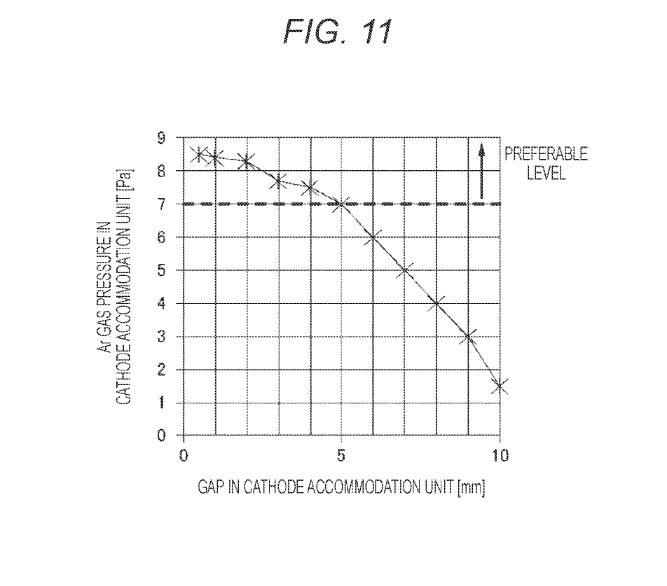

Ar gas pressure in the cathode accommodation unit of the prepared film forming device of each of Examples 4-1 to 4-11 was measured as follows. First, a film forming chamber and the cathode accommodation unit of the prepared film forming device were independently evacuated. The degree of vacuum achieved in the cathode accommodation unit was adjusted to 5.0×10⁻⁵ Pa or lower. Next, Ar gas of the cathode accommodation unit was introduced by the Ar gas introducing unit, and Ar gas pressure in the cathode accommodation unit was measured. Results thereof are illustrated in FIG. 11.

The Ar gas pressure in the cathode accommodation unit can be adjusted to 7.0 Pa or more by setting the gap between the drum and the cathode accommodation unit to be in a range of from 0.5 mm to 5.0 mm. It should be noted that when the Ar gas pressure in the cathode accommodation unit is 7.0 Pa or more, particularly excellent magnetic characteristics can be obtained.

Embodiments, modifications thereof, and Examples of the present technology have been specifically described above. However, the present technology is not limited to the embodiments, modifications thereof, and Examples described above, and various types of modifications are possible based on technical ideas of the present technology.

For example, configurations, methods, steps, shapes, materials, numerical values, and the like exemplified in the embodiments, modifications thereof, and Examples described above are by way of example only, and configurations, methods, steps, shapes, materials, numerical values, and the like different therefrom may be used if necessary.

In addition, configurations, methods, steps, shapes, materials, numerical values, and the like of the embodiments, modifications thereof, and Examples described above may be combined with each other without departing from the gist of the present technology.

In addition, the present technology may adopt the following configurations.

(1)

A film forming device including:

a drum having a circumferential surface;

a cathode accommodation unit disposed to be opposite to the circumferential surface;

a first gas introducing unit which introduces a first gas into the cathode accommodation unit; and

a second gas introducing unit which introduces a second gas between the circumferential surface and the cathode accommodation unit.

(2)

The film forming device according to (1), in which

the first gas introducing unit is an inert gas introducing unit, and

the second gas introducing unit is an oxidation-reactive gas introducing unit.

(3)

The film forming device according to (1) or (2), further including an exhaust unit which exhausts the cathode accommodation unit.

(4)

The film forming device according to any one of (1) to (3), in which the second gas introducing unit introduces the second gas between the circumferential surface and the cathode accommodation unit from an upstream or downstream side of rotation of the drum.

(5)

The film forming device according to any one of (1) to (4), in which a gap between the circumferential surface and the cathode accommodation unit is from 0.5 mm to 5.0 mm.

(6)

The film forming device according to any one of (1) to (5), in which the cathode accommodation unit includes a wall portion having a configuration capable of performing heating and cooling.

(7)

A film forming device including:

a drum having a circumferential surface;

a plurality of cathode accommodation units disposed to be opposite to the circumferential surface;

a first gas introducing unit which introduces a first gas into the plurality of cathode accommodation units; and

a second gas introducing unit which introduces a second gas between the circumferential surface and at least one cathode accommodation unit of the plurality of cathode accommodation units.

(8)

The film forming device according to (7), further including an exhaust unit which exhausts the plurality of cathode accommodation units independently.

(9)

A method for manufacturing a magnetic recording medium, the method including:

forming a magnetic layer on an elongated substrate which travels along a circumferential surface of a drum by sputtering a target accommodated in a cathode accommodation unit while introducing an inert gas into the cathode accommodation unit opposite to the circumferential surface of the drum and introducing an oxidation-reactive gas between the circumferential surface and the cathode accommodation unit.

(10)

The method for manufacturing a magnetic recording medium according to (9), in which the target includes Co.

(11)

The method for manufacturing a magnetic recording medium according to (10), in which the target further includes Pt.

(12)

The method for manufacturing a magnetic recording medium according to (9) or (10), in which the magnetic layer includes Co and Co oxide.

(13)

The method for manufacturing a magnetic recording medium according to any one of (9) to (12), in which variations in magnetic characteristics are within ±10% over a section extending 100 m in a machine direction of the substrate.

(14)

The method for manufacturing a magnetic recording medium according to any one of (9) to (13), further including evacuating the cathode accommodation unit before the sputtering, in which a degree of vacuum achieved in the cathode accommodation unit through the evacuation is 5.0×10⁻⁵ Pa or lower.

(15)

The method for manufacturing a magnetic recording medium according to any one of (9) to (14), further including heating the cathode accommodation unit before the sputtering.

(16)

The method for manufacturing a magnetic recording medium according to any one of (9) to (15), further including cooling the cathode accommodation unit when performing the sputtering.

(17)

A magnetic recording medium including:

an elongated flexible substrate; and

a magnetic layer which is obtained by performing sputtering and includes Co and Co oxide,

in which variations in magnetic characteristics are within ±10% over a section extending 100 m in a machine direction of the substrate.

### REFERENCE SIGNS LIST

11 Substrate
12 Magnetic recording layer
13 Protective layer
14 Lubricant layer
15 Undercoat layer
16 Intermediate layer
21 Film forming chamber
22 Drum
31, 31a, 31b Cathode accommodation unit
32, 32a, 32b Cathode
32T, 32Ta, 32Tb Target
41, 41a, 41b, 51 Gas introducing unit
61, 61a, 61b Exhaust unit

1. A film forming device comprising:
a drum having a circumferential surface;
a cathode accommodation unit disposed to be opposite to the circumferential surface;
a first gas introducing unit which introduces a first gas into the cathode accommodation unit; and
a second gas introducing unit that introduces a second gas between the circumferential surface and the cathode accommodation unit.

2. The film forming device according to claim 1, wherein
the first gas introducing unit is an inert gas introducing unit, and
the second gas introducing unit is an oxidation-reactive gas introducing unit.

3. The film forming device according to claim 1, further comprising an exhaust unit that exhausts the cathode accommodation unit.

4. The film forming device according to claim 1, wherein the second gas introducing unit introduces the second gas between the circumferential surface and the cathode accommodation unit from an upstream or downstream side of rotation of the drum.

5. The film forming device according to claim 1, wherein a gap between the circumferential surface and the cathode accommodation unit is from 0.5 mm to 5.0 mm.

6. The film forming device according to claim 1, wherein the cathode accommodation unit comprises a wall portion having a configuration capable of performing heating and cooling.

7. A film forming device comprising:
a drum having a circumferential surface;
a plurality of cathode accommodation units disposed to be opposite to the circumferential surface;
a first gas introducing unit that introduces a first gas into the plurality of cathode accommodation units; and
a second gas introducing unit that introduces a second gas between the circumferential surface and at least one cathode accommodation unit of the plurality of cathode accommodation units.

8. The film forming device according to claim 7, further comprising an exhaust unit that exhausts the plurality of cathode accommodation units independently.

9. A method for manufacturing a magnetic recording medium, the method comprising:
forming a magnetic layer on an elongated substrate that travels along a circumferential surface of a drum by sputtering a target accommodated in a cathode accommodation unit while introducing an inert gas into the cathode accommodation unit opposite to the circumferential surface of the drum and introducing an oxidation-reactive gas between the circumferential surface and the cathode accommodation unit.

10. The method for manufacturing a magnetic recording medium according to claim 9, wherein the target comprises Co.

11. The method for manufacturing a magnetic recording medium according to claim 10, wherein the target further comprises Pt.

12. The method for manufacturing a magnetic recording medium according to claim 10, wherein the magnetic layer comprises Co and Co oxide.

13. The method for manufacturing a magnetic recording medium according to claim 9, wherein variations in magnetic characteristics are within ±10% over a section extending 100 m in a machine direction of the substrate.

14. The method for manufacturing a magnetic recording medium according to claim 9, further comprising evacuating the cathode accommodation unit before the sputtering,
wherein a degree of vacuum achieved in the cathode accommodation unit through the evacuation is 5.0×10⁻⁵ Pa or lower.

15. The method for manufacturing a magnetic recording medium according to claim 9, further comprising heating the cathode accommodation unit before the sputtering.

16. The method for manufacturing a magnetic recording medium according to claim 9, further comprising cooling the cathode accommodation unit when performing the sputtering.

17. A magnetic recording medium comprising:
an elongated flexible substrate; and
a magnetic layer that is obtained by performing sputtering and includes Co and Co oxide,
wherein variations in magnetic characteristics are within ±10% over a section extending 100 m in a machine direction of the substrate.
